(19) United States
(12) Patent Application Publication
(10) Pub. No.: US 2023/0085957 A1
(43) Pub. Date: Mar. 23, 2023

(54) Integrated optical transceiver

(71) Applicant: Apple Inc., Cupertino, CA (US)

(72) Inventors: Nicolas Hotellier, Jarrie (FR); Arnaud Laflaquière, Paris (FR); Christophe Verove, Le Cheylas (FR); Fei Tan, San Jose, CA (US); Siddharth Joshi, Grenoble (FR)

(21) Appl. No.: 17/866,618

(22) Filed: Jul. 18, 2022

Related U.S. Application Data
(60) Provisional application No. 63/246,803, filed on Sep. 22, 2021.

(51) Int. Cl. H01S 5/026; H01S 5/042; H01S 5/02326; H01S 5/42

(52) U.S. Cl. CPC H01S 5/0262; H01S 5/04256; H01S 5/02326; H01S 5/426

(57) ABSTRACT

An optoelectronic device includes a base chip, including a silicon die having a photodiode disposed at its front surface and a first anode contact and a first cathode contact disposed on the front surface. A laser diode driver circuit on the silicon die supplies an electrical drive signal between the first anode contact and the first cathode contact. An emitter chip includes a III-V semiconductor die, which is mounted with its front side facing toward the front surface of the silicon die. A second anode contact and a second cathode contact are disposed on the front side of the III-V semiconductor die in electrical communication with the first anode contact and the first cathode contact. A VCSEL is disposed on the front side of the III-V semiconductor die in coaxial alignment with the photodiode and receives the drive signal from the second anode contact and the second cathode contact.

### CROSS-REFERENCE TO RELATED APPLICATION

This application claims the benefit of U.S. Provisional Patent Application 63/246,803, filed Sep. 22, 2021, which is incorporated herein by reference.

### FIELD OF THE INVENTION

The present invention relates generally to optoelectronic devices, and particularly to integrated sources and detectors and methods for their manufacture.

### BACKGROUND

Monolithic infrared transceivers include both an infrared emitter, such as a vertical-cavity surface-emitting laser (VCSEL), and an infrared detector, such as a photodiode (PD). The VCSEL and PD may be fabricated either within the same stack of thin-film layers formed on a semiconductor substrate, or within separate stacks formed on one or more substrates. Integrated transceivers of this sort are useful in a variety of applications.

An example of a transceiver comprising a VCSEL and a PD fabricated within the same stack is described in United States Patent Application Publication 2021/0091244, whose disclosure is incorporated herein by reference. This publication describes an optoelectronic device, which includes a semiconductor substrate and a first stack of epitaxial layers, which are disposed over the semiconductor substrate and are configured to function as a photodetector, which emits a photocurrent in response to infrared radiation in a range of wavelengths greater than 940 nm. A second stack of epitaxial layers is disposed over the first stack and configured to function as an optical transmitter with an emission wavelength in the range of wavelengths greater than 940 nm.

Further examples of structures and applications of transceivers integrating a VCSEL and a PD are described in United States Patent Application Publication 2021/0003385, whose disclosure is incorporated herein by reference. This publication describes self-mixing interferometry (SMI) sensors, such as may include vertical cavity surface emitting laser (VCSEL) diodes and resonance cavity photodetectors (RCPDs). Structures for the VCSEL diodes and RCPDs are disclosed. In some embodiments, a VCSEL diode and an RCPD are laterally adjacent and formed from a common set of semiconductor layers epitaxially formed on a common substrate. In some embodiments, a first and a second VCSEL diode are laterally adjacent and formed from a common set of semiconductor layers epitaxially formed on a common substrate, and an RCPD is formed on the second VCSEL diode. In some embodiments, a VCSEL diode may include two quantum well layers, with a tunnel junction layer between them. In some embodiments, an RCPD may be vertically integrated with a VCSEL diode.

### SUMMARY

Embodiments of the present invention that are described hereinbelow provide improved designs and fabrication methods for integrated optical transceivers.

There is therefore provided, in accordance with an embodiment of the invention, an optoelectronic device, which includes a base chip, including a silicon die having front and rear surfaces, a photodiode disposed at the front surface of the silicon die, and a first anode contact and a first cathode contact disposed on the front surface of the silicon die. A laser diode driver circuit is disposed on the silicon die and connected to supply an electrical drive signal between the first anode contact and the first cathode contact. An emitter chip includes a III-V semiconductor die, which has front and rear sides and is mounted with the front side facing toward the front surface of the silicon die. A second anode contact and a second cathode contact are disposed on the front side of the III-V semiconductor die in electrical communication with the first anode contact and the first cathode contact, respectively. A vertical-cavity surface-emitting laser (VCSEL) is disposed on the front side of the III-V semiconductor die in coaxial alignment with the photodiode, and is configured to receive the drive signal from the second anode contact and the second cathode contact and to emit an optical beam through the III-V semiconductor die in response to the drive signal.

In some embodiments, the III-V semiconductor die is mounted on the silicon die so as to define a gap between the VCSEL and the photodiode, and the gap is filled with a dielectric material. In one embodiment, the dielectric material includes a polymer. In another embodiment, the dielectric material is gaseous.

In a disclosed embodiment, the device includes a stack of epitaxial layers disposed on the front side of the III-V semiconductor substrate, wherein the stack is etched to define the VCSEL and to define electrode supports alongside the VCSEL, and wherein the second anode contact and the second cathode contact are disposed on the electrode supports.

Additionally or alternatively, the device includes a microlens disposed on the rear side of the III-V semiconductor die in coaxial alignment with the VCSEL and the photodiode.

In one embodiment, the photodiode is formed within the silicon die. Alternatively, the photodiode is bonded to the front surface of the silicon die.

In a disclosed embodiment, the base chip includes multiple photodiodes, and the emitter chip includes multiple VCSELs in coaxial alignment with respective ones of the photodiodes.

There is also provided, in accordance with an embodiment of the invention, a method for producing an optoelectronic device. The method includes fabricating a photodiode on a front surface of a silicon die and fabricating a laser diode driver circuit on the silicon die. A first anode contact and a first cathode contact are formed on the front surface of the silicon die in electrical communication with the laser diode driver circuit. A vertical-cavity surface-emitting laser (VCSEL) is fabricated on a front side of the III-V semiconductor die and configured to emit an optical beam through the III-V semiconductor die. A second anode contact and a second cathode contact are formed on the front side of a III-V semiconductor die in electrical communication with the VCSEL. The III-V semiconductor die is mounted on the silicon die with the front side of the III-V semiconductor die facing toward the front surface of the silicon die, with the VCSEL in coaxial alignment with the photodiode, and with the first anode contact and the first cathode contact in electrical communication with the second anode contact and the second cathode contact, respectively, so that the laser diode driver circuit can supply an electrical drive signal to the VCSEL.

The present invention will be more fully understood from the following detailed description of the embodiments thereof, taken together with the drawings in which:

### BRIEF DESCRIPTION OF THE DRAWINGS

FIG. 1 is a simplified schematic sectional view of an optoelectronic device, in accordance with an embodiment of the invention;

FIGS. 2A and 2B are schematic sectional views of optoelectronic devices, in accordance with two embodiments of the invention;

FIG. 3 is a flowchart that schematically illustrates the fabrication flow for the optoelectronic device of FIG. 2A, in accordance with an embodiment of the invention;

FIG. 4 is a schematic sectional view of an optoelectronic device, in accordance with another embodiment of the invention;

FIG. 5 is a flowchart that schematically illustrates the fabrication flow for the optoelectronic device of FIG. 4, in accordance with an embodiment of the invention;

FIG. 6 is a schematic sectional view of an optoelectronic device, in accordance with yet another embodiment of the invention; and

FIGS. 7A and 7B are schematic sectional views of optoelectronic devices, in accordance with two other embodiments of the invention.

### DETAILED DESCRIPTION OF EMBODIMENTS

In self-mixing interferometry (SMI), also called self-mixing laser interferometry, an electromagnetic wave is emitted from a laser cavity. The emitted wave is directed toward a target, and a portion of the wave reflected by the object re-enters into the laser cavity. The re-entered wave modulates the intra-cavity electromagnetic wave of the laser. This modulation may be measured to sense the range and/or velocity of the target. The modulation of the intra-cavity electromagnetic wave can advantageously be measured by a photodiode that is vertically integrated with the VCSEL.

The embodiments of the present invention that are described herein provide an integrated optoelectronic device for this sort of SMI applications, as well as other applications of integrated optical transceivers. In the disclosed embodiments, a silicon-technology PD on a silicon substrate is vertically integrated with a VCSEL on a III-V semiconductor die, such as a GaAs die. The PD, along with the VCSEL driver and other supporting circuits, is formed on the silicon substrate, over which the III-V semiconductor die with the VCSEL is then mounted. This arrangement enables a high level of device integration in a compact package, and facilitates the design and fabrication of integrated transceiver arrays. Furthermore, the integration of the silicon PD in this configuration, as opposed to a PD based on III-V semiconductor materials, can be used to extend the spectral range of the device to longer infrared wavelengths, for example 940 nm or more.

In the disclosed embodiments, the optoelectronic device comprises an emitter chip, based on a III-V semiconductor die, and a base chip, based on a silicon die. A laser diode driver circuit, connected to first anode and cathode contacts on the silicon die, and a photodiode are fabricated on the base chip. A VCSEL, connected to second anode and cathode contacts on the III-V semiconductor die, is fabricated on the emitter chip. The emitter chip is mounted on the base chip so that front side of the emitter chip, on which the VCSEL is formed, faces the photodiode and is aligned coaxially with it, and so that the respective anode and cathode contacts on the emitter and base chips are in electrical communication.

The laser diode driver circuit applies an electrical drive signal between the anode and cathode contacts, which causes the VCSEL to emit an optical beam through the III-V semiconductor die (so that the beam exits through the rear side of the die). The PD senses residual optical radiation that exits through the front side of the VCSEL and can thus be used, for example, to measure modulation of the beam in SMI applications. In order to have an unimpeded optical path from the VCSEL to the PD, anodes and cathodes are laterally offset from the VCSEL, as shown in the figures.

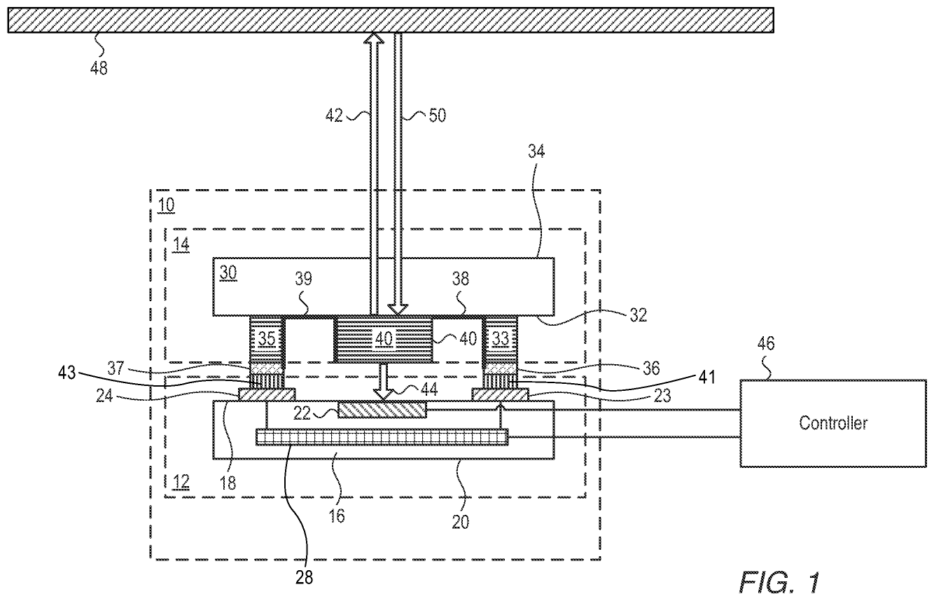

FIG. 1 is a simplified schematic sectional view of an optoelectronic device 10, in accordance with an embodiment of the invention.

Optoelectronic device 10 comprises a base chip 12 and an emitter chip 14. Base chip 12 comprises a silicon die 16 having front and rear surfaces 18 and 20, respectively, and a photodiode 22 disposed at the front surface of the silicon die. Base chip 12 further comprises a first anode contact 23 and a first cathode contact 24 disposed on front surface 18 and a laser diode driver circuit 28 disposed on silicon die 16 and coupled to the first anode and cathode contacts.

Emitter chip 14 comprises a III-V semiconductor die 30, which has front and rear sides 32 and 34, respectively. Emitter chip 14 is mounted with front side 32 facing toward front surface 18 of silicon die 16. Emitter chip 14 also comprises a vertical-cavity surface-emitting laser (VCSEL) 40, which is disposed on front side 32 of III-V semiconductor die 30 in coaxial alignment with photodiode 22. The terms “front” and “rear” are used in the context of the present description and in the claims in accordance with their conventional usage in the art of semiconductor device fabrication: The front side of the chip is the side on which epitaxial layers are formed (specifically, the side of chip 14 on which VCSEL 40 is disposed).

Simultaneously with the fabrication of VCSEL 40, two electrode supports 33 and 35 are formed on front surface 32. A second anode electrode 36 and a second cathode electrode 37 are disposed on respective electrode supports 33 and 35, and coupled by respective conductors 38 and 39 to VCSEL 40. Electrical communication between base chip 12 and emitter chip 14 is established by first and second metal junctions 41 and 43, respectively: first metal junction 41 connects first anode contact 22 to second anode contact 36, and second metal junction 43 connects first cathode contact 24 to second cathode contact 37. Alternatively, anode and cathode contacts 22 and 24 may be connected to anode and cathode contacts 36 and 37, respectively, by any other suitable means that are known in the art.

In response to a drive signal conveyed from driver circuit 28 to VCSEL 40, the VCSEL emits an optical beam 42 through III-V semiconductor die 30. In addition, VCSEL 40 emits a residual beam 44, opposite to beam 42, which impinges on photodiode 22. Photodiode 22 emits a photocurrent, which indicates the strength of the optical signal in beam 44, and thus the intensity of the electromagnetic wave within the cavity of VCSEL 40. (VCSEL 40 typically comprises a quantum well layer sandwiched between upper and lower distributed Bragg reflector (DBR) stacks, as is known in the art, but these details are omitted from FIG. 1 for the sake of simplicity.)

In the pictured embodiment, optoelectronic device 10 is used for detecting a distance to and a relative velocity of an object 48 by directing beam 42 toward the object. A part of beam 42, reflected by object 48, returns to optoelectronic device 10 as a return beam 50, entering VCSEL 40 through III-V semiconductor die 30, and modulating the intracavity electromagnetic wave of the VCSEL. This modulation, in turn, is reflected in the intensity of beam 44. By monitoring the amplitude and/or frequency of the modulated optical power of beam 44 by photodetector 22, a controller 46 can derive the distance to and/or velocity of object 48.

Controller 46 typically comprises a programmable processor, which is programmed in software and/or firmware to carry out the functions that are described herein. Alternatively or additionally, controller 46 comprises hard-wired and/or programmable hardware logic circuits, which carry out at least some of the functions of the controller. Although controller 46 is shown in the figures, for the sake of simplicity, as a single, monolithic functional block, in practice the controller may comprise a single chip or a set of two or more chips, with suitable interfaces for receiving and outputting the signals that are illustrated in the figures and are described in the text. Alternatively, controller 46 may be integrated into base chip 12, with concomitant differences in its structure and functions as compared to a self-standing controller.

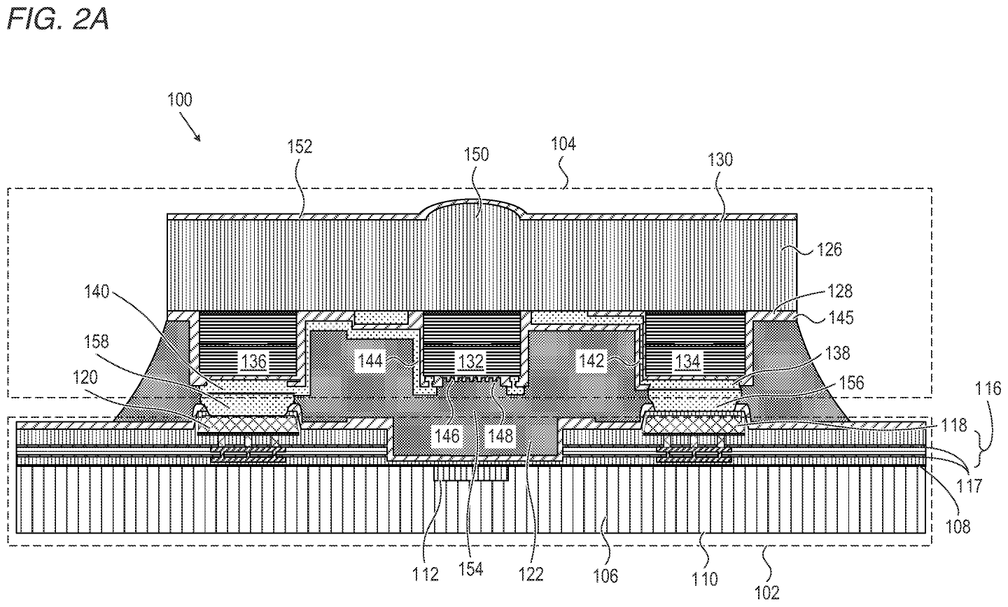

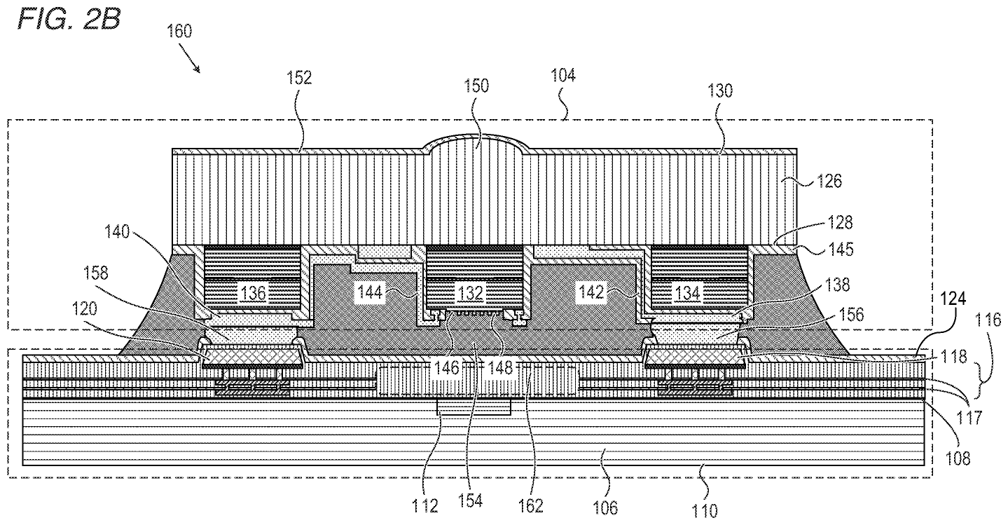

FIG. 2A is a schematic sectional view of an optoelectronic device 100, in accordance with an embodiment of the invention. Optoelectronic device 100 is similar to optoelectronic device 10 of FIG. 1, but is described in more detail.

Optoelectronic device 100 comprises a base chip 102 and an emitter chip 104. Base chip 102 comprises a silicon die 106 having front and rear surfaces 108 and 110, respectively, and a photodiode 112 formed within the silicon die adjacent to front surface 108. A multilayer 116, comprising alternating layers of dielectric material and metal, is deposited over front surface 108. The dielectric material typically comprises barrier layers 117, comprising SiN and/or SiCN, for example. A first anode contact 118 and a first cathode contact 120 are disposed over front surface 108 and coupled to a laser diode driver circuit in silicon die 106 (as shown in FIG. 1) to receive between them an electrical drive signal from the circuit. A cavity 122 is etched above photodiode 112 in multilayer 116 in order to avoid reflections of optical radiation from the interfaces in the multilayer. A silicon-nitride (SiN) layer 124 is deposited over multilayer 116 and cavity 122. Layer 124 functions as a passivation layer, and its thickness is adjusted so that it also serves as an anti-reflection layer within cavity 122.

Emitter chip 104 comprises a III-V semiconductor die 126, which has front and rear sides 128 and 130, respectively. Emitter chip 104 is mounted with front side 128 facing toward front surface 108 of silicon die 106. A vertical-cavity surface-emitting laser (VCSEL) 132 is disposed on front side 128 of III-V semiconductor die 126 in coaxial alignment with photodiode 112. VCSEL 132 comprises a stack of epitaxial layers, which are deposited on die 126 and are etched to define a mesa, from which the laser beam is emitted.

Emitter chip 104 also comprises two additional mesas 134 and 136, which are formed concurrently with the etch of the mesa of VCSEL 132 and function as electrode supports for a second anode contact 138 and a second cathode contact 140. Second anode contact 138 and a second cathode contact 140 are electrically connected by respective conductors 142 and 144 to VCSEL 132 so that conductor 142 forms a p-contact with the VCSEL via die 126 and conductor 144 forms an re-contact with the VCSEL. Electrical communication between first anode contact 118 and second anode contact 138 and between first cathode contact 120 and second cathode contact 140 is provided by respective metal junctions 156 and 158, which have been deposited on the first anode and cathode contacts. This closes the path for an electrical drive signal from the laser diode driver circuit to VCSEL 132. Because contacts 138 and 140 are offset to the sides of VCSEL 132, the optical path between the VCSEL and photodiode 112 is unimpeded.

A SiN-layer 145 has been deposited on the face of emitter chip 104 facing base chip 102, and openings are etched to the SiN-layer as required.

A diffraction grating 146 is etched in the top of the mesa of VCSEL 132, facing photodiode 112, for polarizing the radiation emitted by the VCSEL. An AR-coating 148 is deposited on grating 146 using atomic-layer deposition (ALD), for example.

In the pictured embodiment, a microlens 150 is formed on back side 130 of III-V semiconductor die 126 for control of the geometry of the beam of optical radiation emitted by VCSEL 132 through the die (for example, the geometry of beam 42 in FIG. 1). Microlens 150 may be positioned for steering the emitted beam in a desired direction, as well as for determining the numerical aperture (NA) of the beam. The thickness of die 126 can also be used to increase the optical path length from VCSEL 132 to lens 150 and thus improve the collimation of the transmitted beam. An AR-coating 152 is deposited on lens 150 and back side 130. Alternatively, device 100 may be produced without a microlens on die 126.

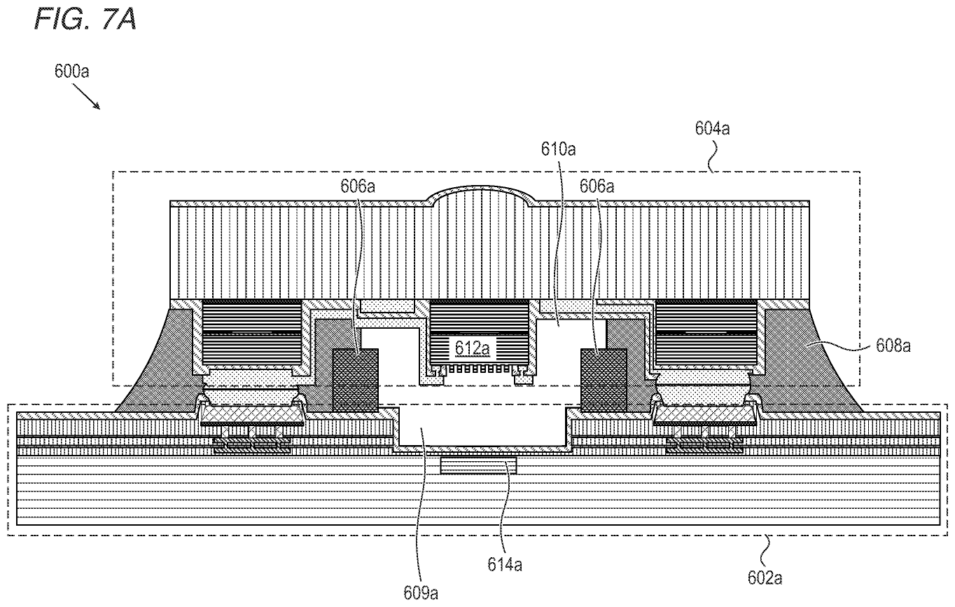

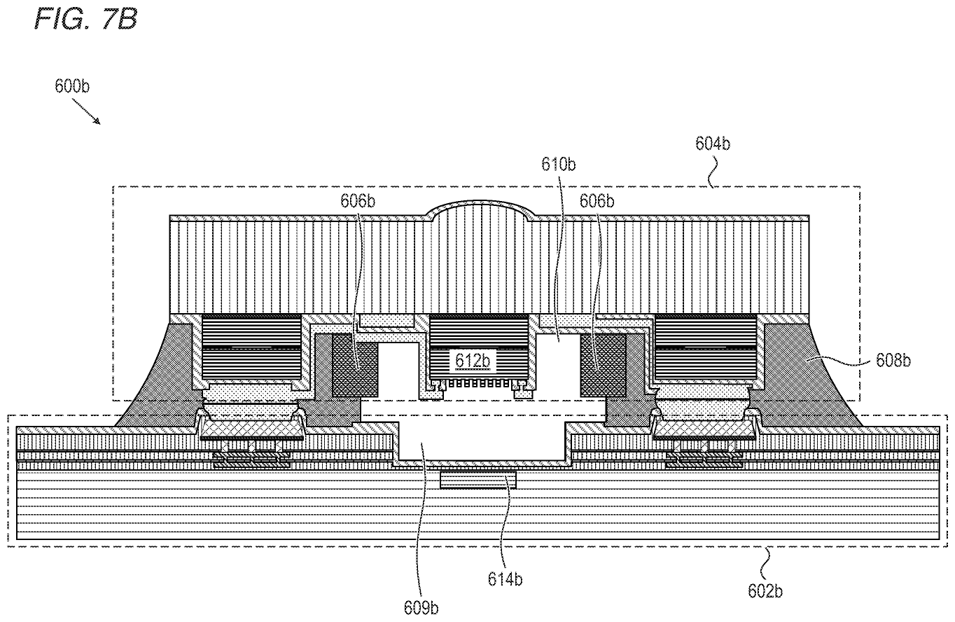

Mounting emitter chip 104 on base chip 102 defines a gap 154 between VCSEL 132 and photodiode 112. Gap 154 is filled with a dielectric material. In the present embodiment, the dielectric material is a transparent polymer. Alternatively, the dielectric material may comprise a gas, for example as shown in FIGS. 7A/B.

FIG. 2B is a schematic sectional view of an optoelectronic device 160, in accordance with an alternative embodiment of the invention. Optoelectronic device 160 is similar to optoelectronic device 100 of FIG. 2A, with the following difference: Instead of an etched cavity 122 in device 100, only SiN and/or SiCN barrier layers 117 have been locally etched in an area 162 above photodiode 112. The thickness of SiN layer 124 in this embodiment is adjusted so that it serves as an anti-reflection layer over photodiode 112.

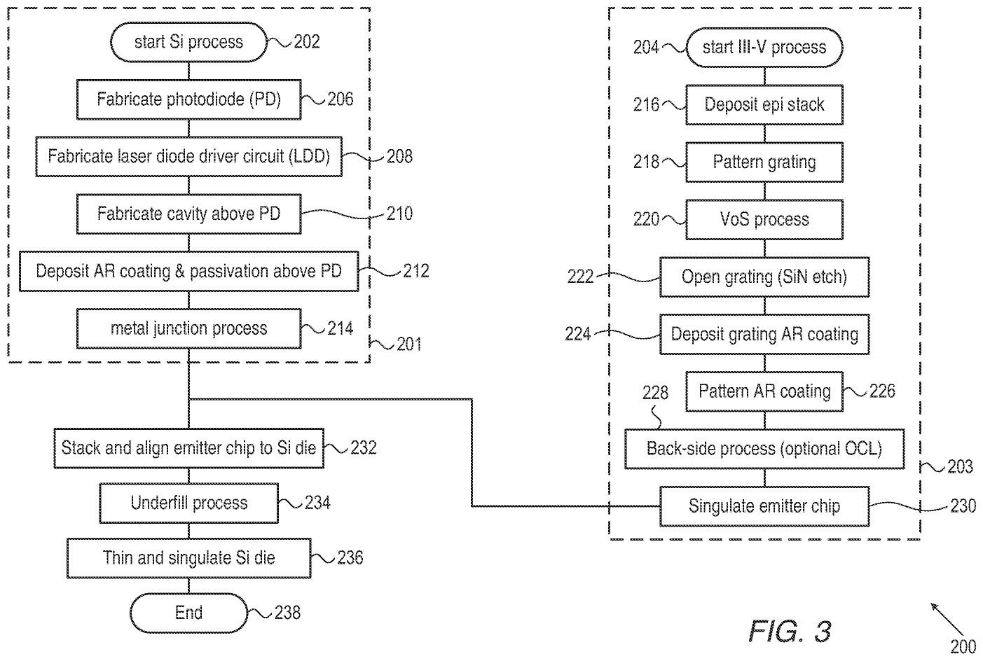

FIG. 3 is a flowchart 200 that schematically illustrates the fabrication flow for optoelectronic device 100, in accordance with an embodiment of the invention. United States Patent Application Publication 2019/0363520, whose disclosure is incorporated herein by reference, describes an example of a VCSEL-on-Si process that can be adapted in implementing certain of the steps in the present fabrication flow, mutatis mutandis.

Flowchart 200 starts as two separate branches 201 and 203, wherein branch 201 comprises a fabrication process of a silicon (Si) wafer, and branch 203 comprises a fabrication process of a III-V semiconductor (such as GaAs) wafer. Branch 201 produces a matrix of dies 106 on the silicon wafer, while branch 203 produces a matrix of dies 126 on the III-V wafer. The fabrication steps that are described below with reference to these dies 106 and 126 are actually carried out concurrently over the entire matrices of dies on the two wafers.

Branch 201 starts in a Si process start step 202. In a photodiode fabrication step 206, photodiode 112 is formed by appropriate doping of die 106. In an LDD fabrication step 208, the laser diode driver circuit is fabricated on die 106 together with first anode and cathode contacts 118 and 120. In a cavity patterning step 210, cavity 122 above photodiode 112 is patterned and etched through multilayer 116. In a deposition step 212, SiN layer 124 is deposited over photodiode 112, functioning both as an AR coating and a passivation layer. In a metal junction process step 214, metal junctions 156 and 158 are deposited on first anode and cathode contacts 118 and 120 and patterned.

Branch 203 starts in a III-V process start step 204. In an epi deposition step 216, an epitaxial stack is deposited over die 126, including a lower DBR stack, a quantum well layer, and an upper DBR stack. In a grating patterning step 218, grating 146 is patterned onto the upper DBR stack. In a VoS (VCSEL-on-silicon) step 220, the fabrication of emitter chip 104 is completed, including etching the mesa of VCSEL 132, as well as mesas 134 and 136. After etching the mesas, one or more metal layers are deposited to define second anode and cathode 138 and 140 and conductors 142 and 144. In a grating etch step 222, SiN-layer 145 above grating 146 is etched based on the patterning in step 218. In a grating AR coating step 224, a suitable thin-film coating is deposited over grating 146, and in an AR patterning step 226, the coating is patterned. In a back-side process step 228, microlens 150 is optionally formed by etching the back side of die 126, and AR-coating 152 is deposited. In an emitter chip singulation step 230, emitter chip 104 is singulated.

Branches 201 and 203 join in a stacking step 232, wherein the singulated emitter chip 104 is stacked on and aligned with Si die 106. In an underfill step 234, cavity 154 between emitter chip 104 and Si die 106 is filled with underfill material. In a Si die thinning and singulation step 236, Si die 106 is thinned and singulated to form base chip 102. The process ends in an end step 238.

The fabrication of optoelectronic device 160 (FIG. 2B) follows a similar flow, with the difference that cavity patterning step 210 is replaced by a suitable local etching step of barrier layers 117.

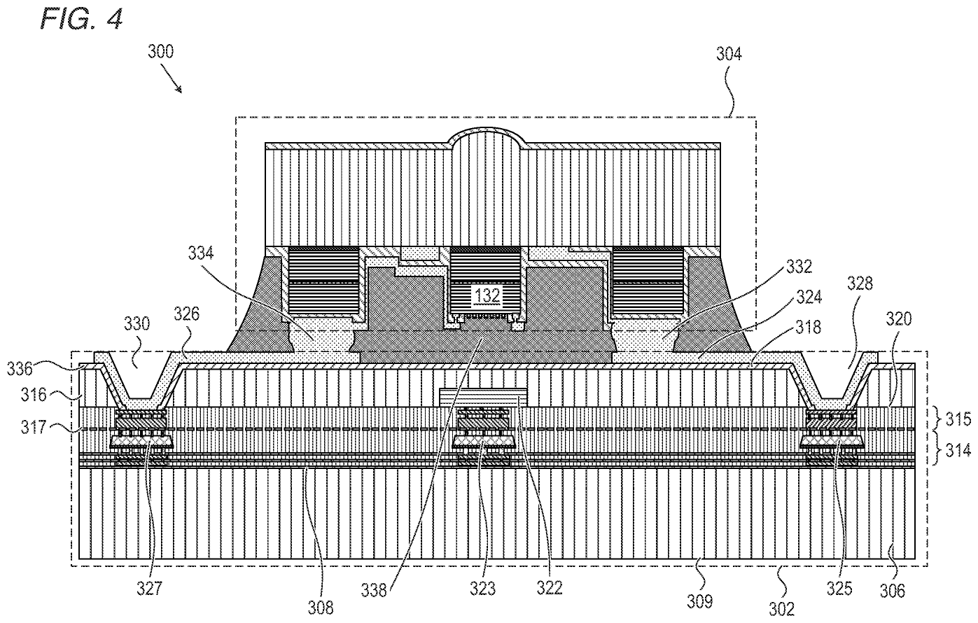

FIG. 4 is a schematic sectional view of an optoelectronic device 300, in accordance with another embodiment of the invention. Optoelectronic device 300 comprises a base chip 302 and an emitter chip 304, wherein the emitter chip is identical to emitter chip 104 (FIG. 1). However, base chip 302 differs from base chip 102, as will be detailed hereinbelow.

Base chip 302 comprises a Si die 306 with a front surface 308 and a back surface 309, and with laser diode driver circuits and processing circuits (not shown) formed in the die and a multilayer 314 containing metal traces and contacts deposited over die 306. Base chip 302 further comprises an infrared back-side illuminated (IR BSI) wafer 316 comprising a back side 318 and a front side 320. A photodiode 322 is formed on front side 320 and connected through a contact 323 in multilayer 314 to Si die 306 and its processing circuits. Wafer 316 further comprises a dielectric layer 315. Photodiode 322 receives IR optical radiation from back side 318 through IR BSI wafer 316. Front side 320 of IR BSI wafer 316 is bonded to front surface 308 of Si die 306 so that dielectric layers 314 and 315 are bonded along an interface 317. As emitter chip 304 is mounted on and aligned with base chip 302 with VCSEL 132 facing the base chip, optical radiation emitted by the VCSEL is received by photodiode 322 through IR BSI wafer 316. Back side 318 of IR BSI wafer 316 is coated with a passivation layer 336, also serving as an AR coating in order to reduce reflective losses of optical radiation emitted by VCSEL 132 toward photodiode 322.

An anode trace 324 and a cathode trace 326 are formed in a redistribution layer (RDL) of conductors on back side 318 of IR BSI wafer 316. Traces 324 and 326 make electrical contact with an anode contact 325 and a cathode contact 327 of the laser diode driver circuit through respective vias 328 and 330 opened through the IR BSI wafer. Traces 324 and 326 are connected to the respective anode and cathode contacts in emitter chip 304 by metal junctions 332 and 334. Similarly to optoelectronic device 100, a gap 338 defined between base chip 302 and emitter chip 304 is filled with a dielectric material.

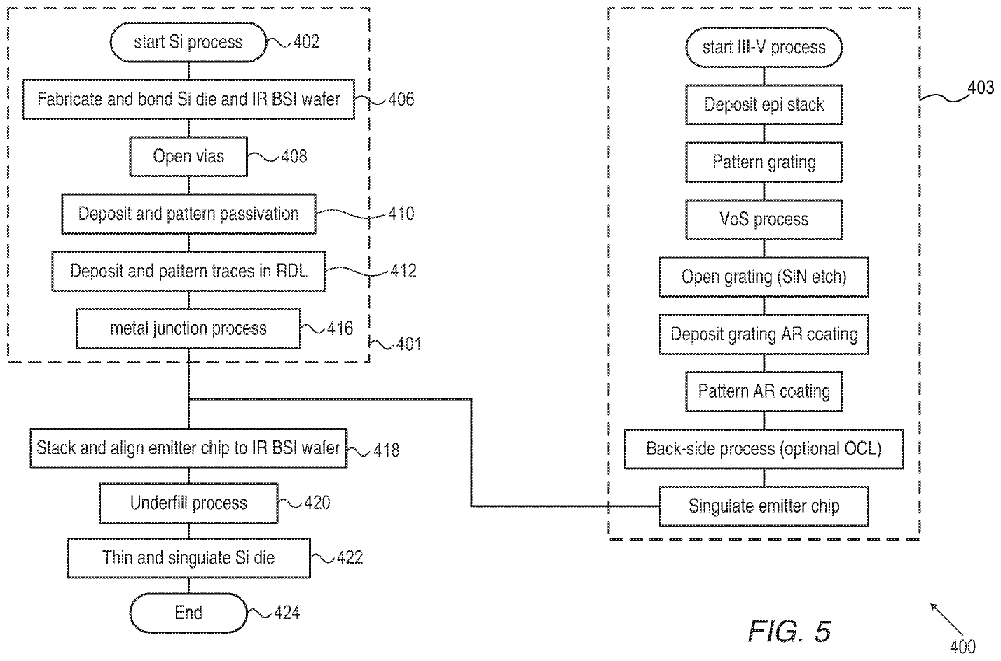

FIG. 5 is a flowchart 400 that schematically illustrates the fabrication flow for optoelectronic device 300, in accordance with an embodiment of the invention.

Flowchart 400 starts with two branches 401 and 403. Branch 401 comprises a Si fabrication process for fabricating Si die 306 and IR BSI wafer 316 and bonding the two together to form base chip 302 (FIG. 4). Branch 403 comprises a III-V fabrication process identical to branch 203 of flowchart 200 (FIG. 3). Details of branch 403 are therefore omitted from the description that follows.

In a Si start step 402, the processing of two Si wafers, one comprising IR BSI wafer 316 and the other comprising Si die 306 (FIG. 4), is started. In a Si fabrication step 406, Si die 306 is processed to form laser diode driver circuits and processing circuits, and IR BSI wafer 316 is processed to form photodiode 322. IR BSI wafer 316 is then bonded to Si die 306 and thinned. In a via opening step 408, vias 328 and 330 are opened through IR BSI wafer 316. In a passivation step 410, passivation layer 336 is deposited over back side 318 of IR BSI wafer 316 and opened at vias 328 and 330. In an RDL step 412, traces 324 and 326 are deposited and patterned for establishing electrical communication to contacts 325 and 327 through vias 328 and 330, respectively. In a metal junction step 416, metal junctions 332 and 334 are formed. In a stacking and aligning step 418, the two branches 401 and 403 are joined in stacking and aligning emitter chip 304 on the bonded IR BSI wafer 316 and Si die 306. In an underfill step 420, gap 338 is filled with a dielectric material. In a Si thinning and singulation step 422, Si die 106 is thinned and singulated. The process ends in an end step 424.

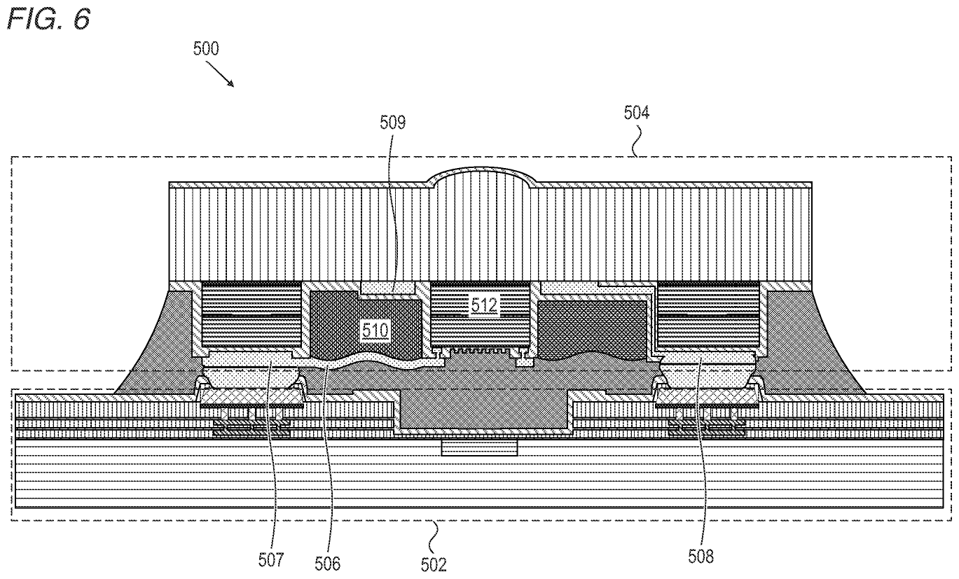

FIG. 6 is a schematic sectional view of an optoelectronic device 500, in accordance with yet another embodiment of the invention.

Optoelectronic device 500 comprises a base chip 502 and an emitter chip 504, wherein base chip 502 is identical to base chip 102 (FIG. 2A). Emitter chip 504 is similar to emitter chip 104, except that an additional polymer spacer 510 is formed around the mesa of a VCSEL 512 on chip 504, and a conductor 506 extending across spacer 510 connects a cathode contact 507 of chip 504 to the cathode of VCSEL 512. An anode contact 508 is connected to the VCSEL anode by a conductor 509 running beneath spacer 510. Polymer spacer 510 acts as a low-k dielectric layer between cathode conductor 506 and anode conductor 509, reducing the capacitance of the drive circuit and thus improving the electrical performance of optoelectronic device 500 relative to device 100.

FIGS. 7A and 7B are schematic sectional views of optoelectronic devices 600a and 600b, respectively, in accordance with two other embodiments of the invention. Optoelectronic devices 600a and 600b comprise respective base chips 602a and 602b and emitter chips 604a and 604b. With the exception of the details described hereinbelow, base chips 602a and 602b are identical to base chip 102 and emitter chips 604a and 604b are identical to emitter chip 104 (FIG. 2A).

Optoelectronic devices 600a and 600b, however, are modified to prevent underfill material 608a and 608b from filling respective gaps 609a and 609b between a VCSEL 612a and a photodiode 614a and between a VCSEL 612b and a photodiode 614b. The underfill materials 608a and 608b are kept away from the gaps by respective polymer dams 606a and 606b, wherein polymer dam 606a is formed in base chip 602a as a circular dam around photodiode 6124a, and polymer dam 606b is formed in emitter chip 604b as a circular dam around VCSEL 612b. Dams 606a and 606b permit the respective gaps 609a and 609b to be filled by gas (including ambient atmosphere) or vacuum, thus reducing the absorption and scattering of the optical radiation by the polymer underfill material used in the preceding embodiments.

For the sake of simplicity of illustration, the embodiments shown in the figures include only a since VCSEL and a single photodiode. The principles of the present invention, however, may be applied in producing emitter chips comprising arrays of multiple VCSELs, along with base chips comprising arrays of photodiodes, and bonding the chips together to create multi-beam transceiver devices in which each VCSEL is aligned with a respective photodiode. The arrays of VCSELs and photodiodes may comprise a single row or two or more parallel rows of VCSELs and photodiodes.

It will thus be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An optoelectronic device, comprising:
a base chip, comprising:
a silicon die having front and rear surfaces;
a photodiode disposed at the front surface of the silicon die;
a first anode contact and a first cathode contact disposed on the front surface of the silicon die;
a laser diode driver circuit disposed on the silicon die and connected to supply an electrical drive signal between the first anode contact and the first cathode contact; and
an emitter chip, comprising:
a III-V semiconductor die, which has front and rear sides and is mounted with the front side facing toward the front surface of the silicon die;
a second anode contact and a second cathode contact disposed on the front side of the III-V semiconductor die in electrical communication with the first anode contact and the first cathode contact, respectively; and
a vertical-cavity surface-emitting laser (VCSEL), which is disposed on the front side of the III-V semiconductor die in coaxial alignment with the photodiode, and which is configured to receive the drive signal from the second anode contact and the second cathode contact and to emit an optical beam through the III-V semiconductor die in response to the drive signal.

2. The device according to claim 1, wherein the III-V semiconductor die is mounted on the silicon die so as to define a gap between the VCSEL and the photodiode, and wherein the gap is filled with a dielectric material.

3. The device according to claim 2, wherein the dielectric material comprises a polymer.

4. The device according to claim 2, wherein the dielectric material is gaseous.

5. The device according to claim 1, and comprising a stack of epitaxial layers disposed on the front side of the III-V semiconductor substrate, wherein the stack is etched to define the VCSEL and to define electrode supports alongside the VCSEL, and wherein the second anode contact and the second cathode contact are disposed on the electrode supports.

6. The device according to claim 1, and comprising a microlens disposed on the rear side of the III-V semiconductor die in coaxial alignment with the VCSEL and the photodiode.

7. The device according to claim 1, wherein the photodiode is formed within the silicon die.

8. The device according to claim 1, wherein the photodiode is bonded to the front surface of the silicon die.

9. The device according to claim 1, wherein the base chip comprises multiple photodiodes, and the emitter chip comprises multiple VCSELs in coaxial alignment with respective ones of the photodiodes.

10. A method for producing an optoelectronic device, the method comprising:
fabricating a photodiode on a front surface of a silicon die;
fabricating a laser diode driver circuit on the silicon die;
forming a first anode contact and a first cathode contact on the front surface of the silicon die in electrical communication with the laser diode driver circuit;
fabricating a vertical-cavity surface-emitting laser (VCSEL) on a front side of the III-V semiconductor die and configured to emit an optical beam through the III-V semiconductor die;
forming a second anode contact and a second cathode contact on the front side of a III-V semiconductor die in electrical communication with the VCSEL;
mounting the III-V semiconductor die on the silicon die with the front side of the III-V semiconductor die facing toward the front surface of the silicon die, with the VCSEL in coaxial alignment with the photodiode, and with the first anode contact and the first cathode contact in electrical communication with the second anode contact and the second cathode contact, respectively, so that the laser diode driver circuit can supply an electrical drive signal to the VCSEL.

11. The method according to claim 10, wherein the III-V semiconductor die is mounted on the silicon die so as to define a gap between the VCSEL and the photodiode, and the method comprises filling the gap with a dielectric material.

12. The method according to claim 11, wherein the dielectric material comprises a polymer.

13. The method according to claim 11, wherein the dielectric material is gaseous.

14. The method according to claim 10, wherein fabricating the VCSEL comprises fabricating a stack of epitaxial layers on the front side of the III-V semiconductor substrate, and
wherein forming the second anode contact and the second cathode comprises etching the stack to define electrode supports alongside the VCSEL, and depositing the second anode contact and the second cathode contact on the electrode supports.

15. The method according to claim 10, and comprising forming a microlens on a rear side of the III-V semiconductor die in coaxial alignment with the VCSEL and the photodiode.

16. The method according to claim 10, wherein fabricating the photodiode comprises forming the photodiode within the silicon die.

17. The method according to claim 10, wherein fabricating the photodiode comprises bonding the photodiode to the front surface of the silicon die.

18. The method according to claim 10, wherein fabricating the photodiode comprises forming multiple photodiodes on the silicon die, and wherein fabricating the VCSEL comprises forming multiple VCSELs on the III-V semiconductor die in coaxial alignment with respective ones of the photodiodes.
